(19) United States
(12) Patent Application Publication
(10) Pub. No.: US 2012/0244032 A1
(43) Pub. Date: Sep. 27, 2012

(54) METHOD AND APPARATUS FOR LASER ABLATION

(75) Inventors: Reijo Lappalainen, Hiltulanlahti (FI); Vesa Myllymäki, Helsinki (FI); Jukka Häyrynen, Helsinki (FI)

(73) Assignee: PICODEON LTD OY, Helsinki (FI)

(21) Appl. No.: 13/499,530

(22) PCT Filed: Oct. 4, 2010
(86) PCT No.: PCT/FI2010/050771

§ 371 Date: Jun. 12, 2012

(30) Foreign Application Priority Data
Oct. 2, 2009 (FI) 20096012

(51) Int. Cl. C23C 14/28; C22C 19/03; C22C 28/00; C23C 14/16; C22C 5/04

(52) U.S. Cl. 420/433; 427/562; 118/723 R; 420/461; 420/462; 420/441

(57) ABSTRACT

In order to produce a coating on a substrate, the substrate is placed adjacent to a target. Material is cold ablated off the target by focusing a number of consecutive laser pulses on the target, thus producing a number of consecutive plasma fronts that move at least partly to the direction of said substrate. The time difference between said consecutive laser pulses is so short that constituents resulting from a number of consecutive plasma fronts form a nucleus on a surface of the substrate where a mean energy of said constituents allows the spontaneous formation of a crystalline structure.

### TECHNICAL FIELD

The invention in related to the production of crystalline structures, either in the form of a coating on a surface or as crystalline particles in free space.

### BACKGROUND OF THE INVENTION

Methods for producing a coating typically involve exposing the substrate to be coated to a coating substance that appears in the form of a liquid, vapour, or plasma (or some mixture of these). Atoms, ions, molecules or other constituent particles of the coating substance adhere to the substrate surface, so that when a sufficient surface density of adhered particles is achieved, eventually a coating is formed. Coating methods differ largely from each other depending on how the liquid, vapour, or plasma state of the coating substance is created.

Coating by laser ablation constitutes a specific branch of coating methods, in which the coating substance is brought in the form of a solid to the vicinity of the substrate to be coated. A powerful, pulsed laser beam is repeatedly focused onto the solid surface of the coating substance, which is also known as the target, so that each laser pulse causes a microscopic magnitude of the coating substance to turn into highly energetic plasma. The constituents of the plasma plume fly basically outwards into each free direction from the point hit by the laser pulse. If the geometry is right, most of the plasma hits the substrate to be coated, where it adheres very tightly because of the high speed at which it arrived. One of the advantageous properties of laser ablation coating is its high material efficiency, meaning that a very high percentage of the coating substance shot off the target will end up in the completed coating.

Characteristics of laser ablation vary depending on a large number of parameters, including the power density delivered by the laser pulse to the target, one factor of which is the pulse length in time. Each target material has a characteristic ablation threshold, meaning a critical power density that must be achieved in order to create plasma. Nanosecond lasers deliver a pulse length in the range of nanoseconds, while picosecond and femtosecond lasers are also known and even shorter pulse lengths are aimed at. Picosecond lasers have the known capability of causing cold ablation, which means that essentially the whole energy of the laser pulse is converted into kinetic energy of the plasma, and very little energy is absorbed in the target in the form of heat. The advantageous properties of cold ablation have been described in patent applications like PCT/FI2007/000045, PCT/FI2007/000046, PCT/FI2007/000048, PCT/FI2007/000049, and PCT/FI2007/000050, which are incorporated herein by reference.

For some applications, it could be advantageous if the coating had more or less crystalline structure. What is considered crystalline is a matter of definition. According to a widely accepted general characterisation, a solid material is considered to have a crystalline structure if its constituent atoms, molecules, or ions are arranged in an orderly repeating pattern that extends in all three spatial dimensions. In principle the microscopic structure of a solid coating may lie anywhere on the continuous scale ranging from completely amorphous (with no long-range order at all) to absolutely pure monocrystalline, where the regular crystal lattice continues throughout the whole coating without any grain boundaries or lattice faults.

An interesting subrange somewhere on said scale between extremities represents microcrystalline coating structures, where the coating consists of a very large number of adjoining crystal grains of microscopic size. The determination whether a coating should be considered amorphous, quasicrystalline, paracrystalline, microcrystalline, polycrystalline or monocrystalline can be made e.g. by examining the structure of the coating with X-ray diffraction and noting, what is the dominating response in the diffraction measurement. Also other known methods exist for examining the degree of crystallinity of a given solid material, but because the transitions between different forms of crystallinity are not sharp, the result is typically announced so that the examined material is predominantly of one form, instead of being classified exclusively as one.

In addition to coatings, crystalline structures may have utility of their own also in the form of crystalline particles in free space. Nanotechnology has shown that particles in the size range from nanometres to micrometres can be used for various purposes, and they may have surprising characteristics that differ significantly from the usual characteristics of the same materials in macroscopic scale.

Cold ablation has not been considered as a good candidate process for producing crystalline structures. This fact is actually a consequence of the process being “cold”: the macroscopic temperature of the target and the substrate can remain low enough for e.g. paper, a polymer or other heat sensitive matter to be used as one or both, even if the substrate was placed relatively near the target. Plasma constituents that hit a cold substrate will experience very fast cooling, which means that the atoms, ions, or molecules cannot travel to their appropriate lattice sites before they lose their mobility. Certain methods have been suggested for increasing the degree of crystallinity in a coating made by cold ablation. These include e.g. heating the coated substrate after forming the coating and allowing it to cool, so that the coating experiences a kind of annealing. The use of heating may have the disadvantageous consequence of making the process again unsuitable for heat sensitive materials. Additionally heating may cause unwanted diffusion at the interface between the substrate and coating materials, as well as unwanted chemical reactions such as oxidization.

### SUMMARY OF THE INVENTION

According to an advantageous coating aspect of the invention there is provided a method and an arrangement for producing a crystalline coating in a process that involves cold ablation for creating plasma from which the coating will be formed. According to another advantageous coating aspect of the invention there is provided a method and apparatus of the mentioned kind that do not require excessive heating of the substrate. According to yet another advantageous coating aspect of the invention there is provided a method and apparatus for producing a crystalline coating with a wide range of applicable materials that can be selected both for the substrate and for the coating. According to a yet another advantageous coating aspect of the invention there is provided a method and an arrangement for producing a crystalline coating on substrates of a wide range of different geometries.

According to an advantageous particle aspect of the invention there is provides a method and an arrangement for producing particles with crystalline structures in a process that involves cold ablation for creating plasma from which the particles will be formed.

The advantageous aspects of the invention are achieved by delivering ablating laser pulses to the target so quickly in succession that the plasma constituents ejected by one laser pulse have not been cooled below temperatures that allow nucleation and crystallization before the plasma constituents ejected by the subsequent laser pulse arrive, thus maintaining an energy level of the constituents of the coating or particles sufficiently high for a sufficiently long time for crystalline structures to form.

A method according to an advantageous embodiment of the invention is characterised in that it comprises
placing the substrate adjacent to a target, and
cold ablating material off the target by focusing a number of consecutive laser pulses on the target, thus producing a number of consecutive plasma fronts that move at least partly to the direction of said substrate;
   wherein the time difference between said consecutive laser pulses is so short that on said substrate, constituents resulting from a number of consecutive plasma fronts form a nucleus where a mean energy of said constituents allows the spontaneous formation of a crystalline structure.

An arrangement according to an advantageous embodiment of the invention comprises
a target holding unit configured to hold a target in place,
substrate holder and moving robotics configured to hold in place and move a substrate adjacent to said target,
a laser pulse generation unit configured to generate a pulsed laser beam capable of cold ablating the material of said target, and
laser optics configured to guide the pulsed laser beam to said target for producing a number of consecutive plasma fronts that move at least partly to the direction of said substrate;
   and is characterized in that the laser pulse generation unit is configured to use a time difference between consecutive laser pulses that is so short that on said substrate, constituents resulting from a number of consecutive plasma fronts form a nucleus where a mean energy of said constituents allows the spontaneous formation of a crystalline structure.

A coating and a product according to advantageous embodiments of the invention are characterised in that they have been produced by a method of the kind described above.

A method for producing particles with crystalline structure according to an advantageous embodiment of the invention comprises:
cold ablating material off a target by focusing a number of consecutive laser pulses on the target, thus producing a number of consecutive plasma fronts that move at least partly to a direction away from said target;
   wherein the time difference between said consecutive laser pulses is so short that in a reaction space located off the target, constituents resulting from a number of consecutive plasma fronts form a nucleus where a mean energy of said constituents allows the spontaneous formation of a crystalline structure.

An arrangement for producing particles with crystalline structure according to an advantageous embodiment of the invention comprises:
a target holding unit configured to hold a target in place,
a laser pulse generation unit configured to generate a pulsed laser beam capable of cold ablating the material of said target, and
laser optics configured to guide the pulsed laser beam to said target for producing a number of consecutive plasma fronts that move at least partly to a direction away from said target;
   and is characterized in that the laser pulse generation unit is configured to use a time difference between consecutive laser pulses that is so short that in a reaction space located off the target, constituents resulting from a number of consecutive plasma fronts form a nucleus where a mean energy of said constituents allows the spontaneous formation of a crystalline structure.

The constituents of the plasma plume, which was created by the laser pulse hitting the target surface, are in a highly energetic state during the time when they fly from the ablation point towards the surface of the substrate to be coated. Interaction with the solid matter of the substrate, as well as other mechanisms of de-energization, will cause this energy to be dissipated in a process that is characterised by a certain time constant. Said time constant will depend on a large number of parameters, including but not being limited to the selection of the substrate and coating materials, the topology and crystal level structure of the substrate surface, possible primerization of the substrate surface, the macroscopic temperature of the target and substrate bodies, the pressure and material composition of the atmosphere around the reaction area, the distance and geometric factors of the target and the substrate, as well as the power and pulse length of the laser pulse. For the purposes of the present invention it is important to note that said time constant is finite, i.e. the process in which the plasma constituents becomes de-energized on the surface of the substrate does not take place instantaneously. During a certain period of time after having hit the substrate, the constituents that are to form the coating may still be at an energy state that is high enough to allow certain mobility in the lattice structure of the coating that is being formed.

If a large enough number of coating constituents is located close enough to each other on the substrate surface, and a sufficient number of said constituents possess enough energy to allow mobility, they will tend to arrange themselves in a characteristic crystal structure of the coating material and release the associated latent heat of fusion. According to an aspect of the present invention, the favourable conditions for nucleation and resulting crystallization can be established by repeatedly delivering cold ablating laser pulses to the target rapidly in succession. Intuitively one may consider the situation so that the coating constituents resulting from one plasma plume are still “sizzling” on the substrate surface when the next front of plasma arrives, and this process is repeated a number of times, so that the sizzling, almost fluid layer of coating constituents will eventually have sufficient time and density to form nuclei, and consequently solidify at least partly in crystalline form.

The term nucleus (and its plural form nuclei) should not be confused with the nucleus of an atom. This description concerns the formation of nuclei as the starting points of crystalline structures. In this sense, nucleation is considered to mean the extremely localized budding of a distinct thermodynamic phase; which in this case is the solid phase. If a nucleus of this kind is stabile enough and the thermodynamic conditions are also otherwise appropriate, the result is the growth of a crystalline structure around the starting point formed by the nucleus.

Increasing the continuous pulse frequency of a cold ablating pulsed laser may become difficult due to inherent limitations in the system setup, and/or disadvantageous side effects. However, burst mode lasers can be used to produce laser pulse trains where a rapid burst of pulses at a very high repetition frequency is followed by a longer rest period, after which the same cycle is started again. The repeated fronts of plasma produced during a rapid burst of laser pulses may create the advantageous crystallization conditions on the substrate surface locally, leading to at least some degree of a crystalline structure of the completed coating.

The advantageous characteristics of burst mode lasers described above are also applicable to the forming of crystalline particles instead of a coating. Various ways exist for controlling the deceleration of the plasma constituents and the initiation of nucleation. It is thus possible to make nucleation and crystallization take place already in the flying plasma, resulting in the formation of particles with crystalline structure. A substrate is then not needed in the same sense as in coating, but instead some kind of particle collecting means are employed to collect the formed crystalline particles for later use.

The novel features which are considered as characteristic of the invention are set forth in particular in the appended claims. The invention itself, however, both as to its construction and its method of operation, together with additional objects and advantages thereof, will be best understood from the following description of specific embodiments when read in connection with the accompanying drawings.

The exemplary embodiments of the invention presented in this patent application are not to be interpreted to pose limitations to the applicability of the appended claims. The verb “to comprise” is used in this patent application as an open limitation that does not exclude the existence of also unrecited features. The features recited in depending claims are mutually freely combinable unless otherwise explicitly stated.

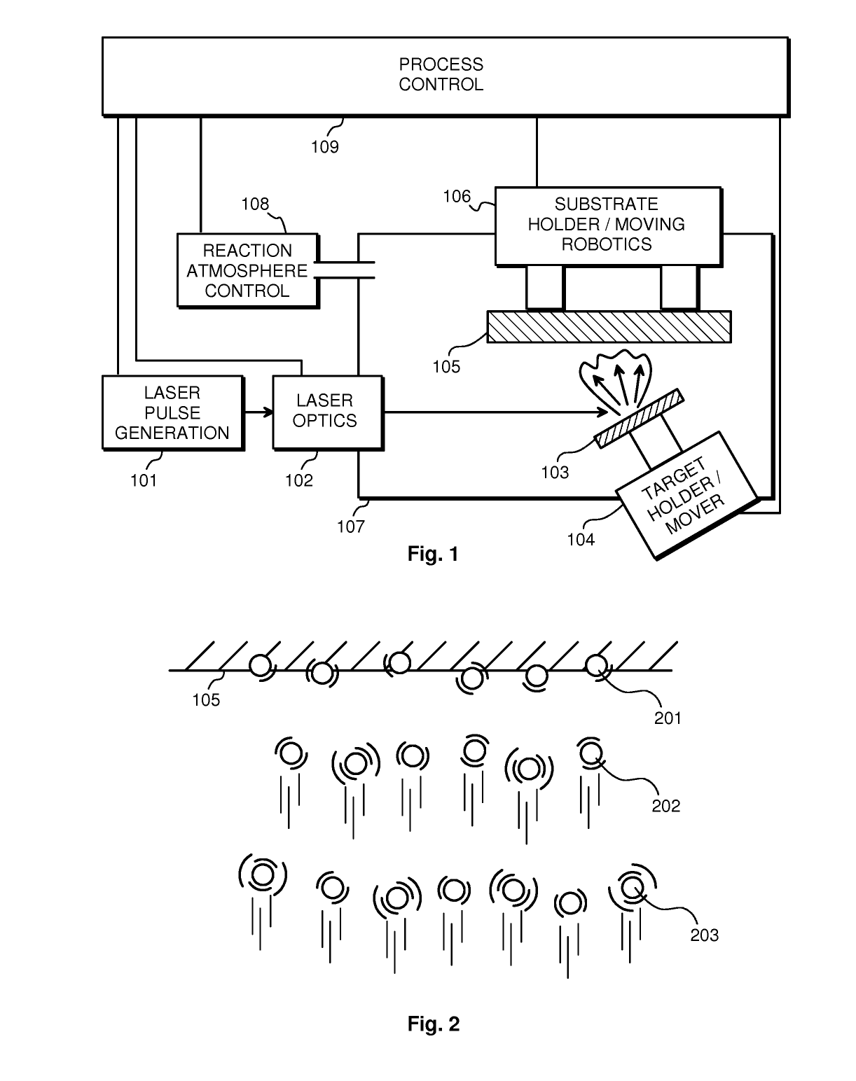

FIG. 1 illustrates an arrangement for producing a coating,

FIG. 2 illustrates the principle of successive plasma fronts,

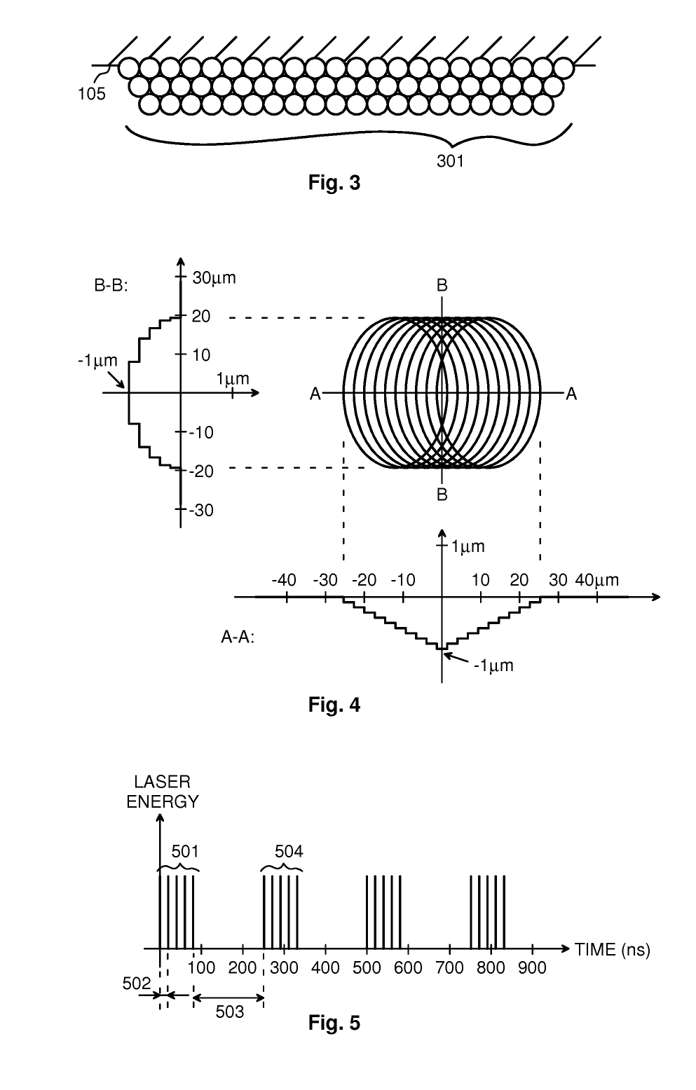

FIG. 3 illustrates a crystalline structure of a coating,

FIG. 4 illustrates the depth profiles of a void eaten out by cold ablation,

FIG. 5 illustrates the principle of burst mode in producing laser pulses,

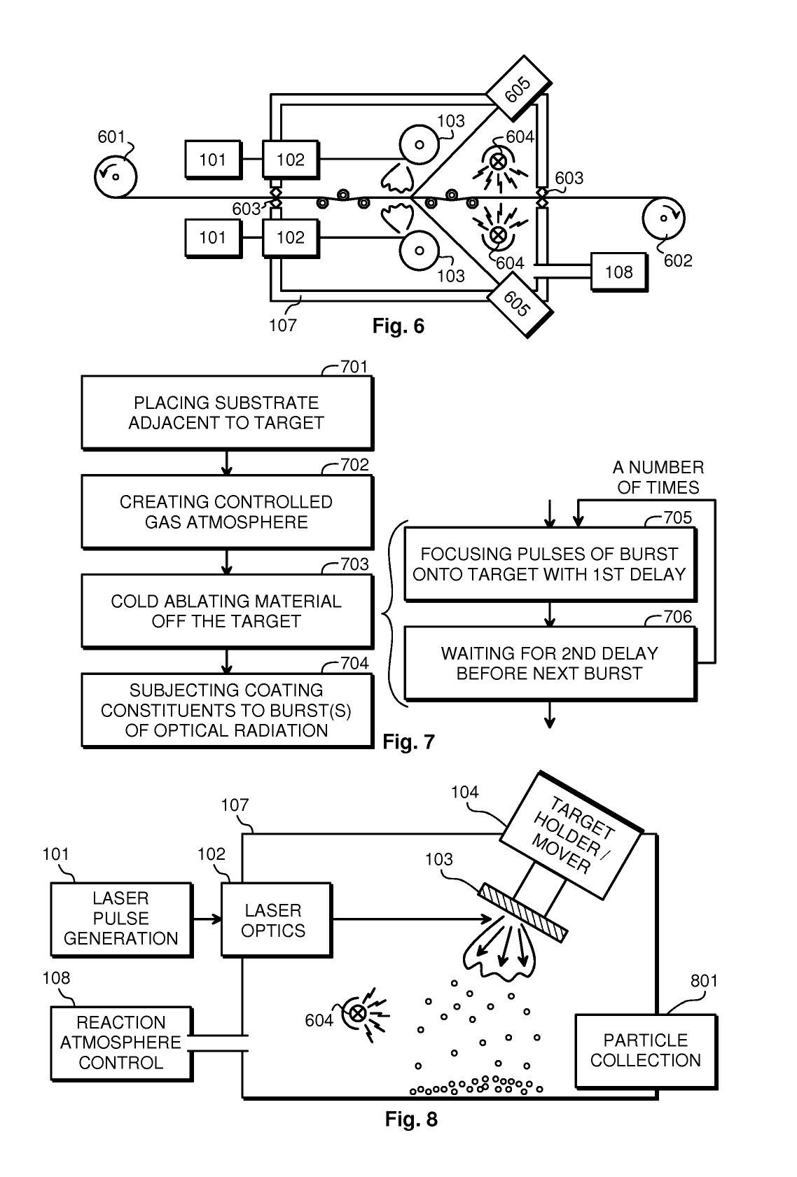

FIG. 6 illustrates an arrangement that includes an annealing stage,

FIG. 7 illustrates a method according to an embodiment of the invention,

FIG. 8 illustrates an arrangement for producing crystalline particles,

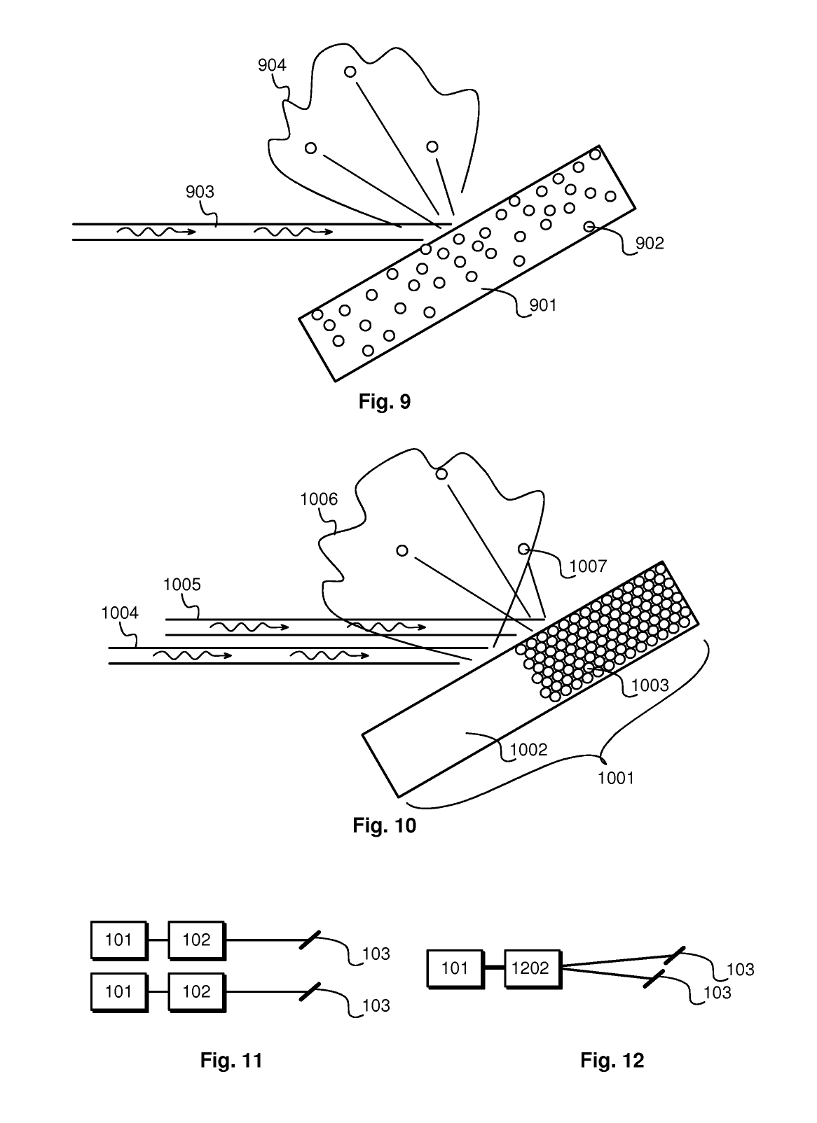

FIG. 9 illustrates the use of a doped target,

FIG. 10 illustrates the use of a composite target,

FIG. 11 illustrates the use of two parallel pulsed lasers for cold ablation,

FIG. 12 illustrates the use of beam splitting laser optics for cold ablation, and

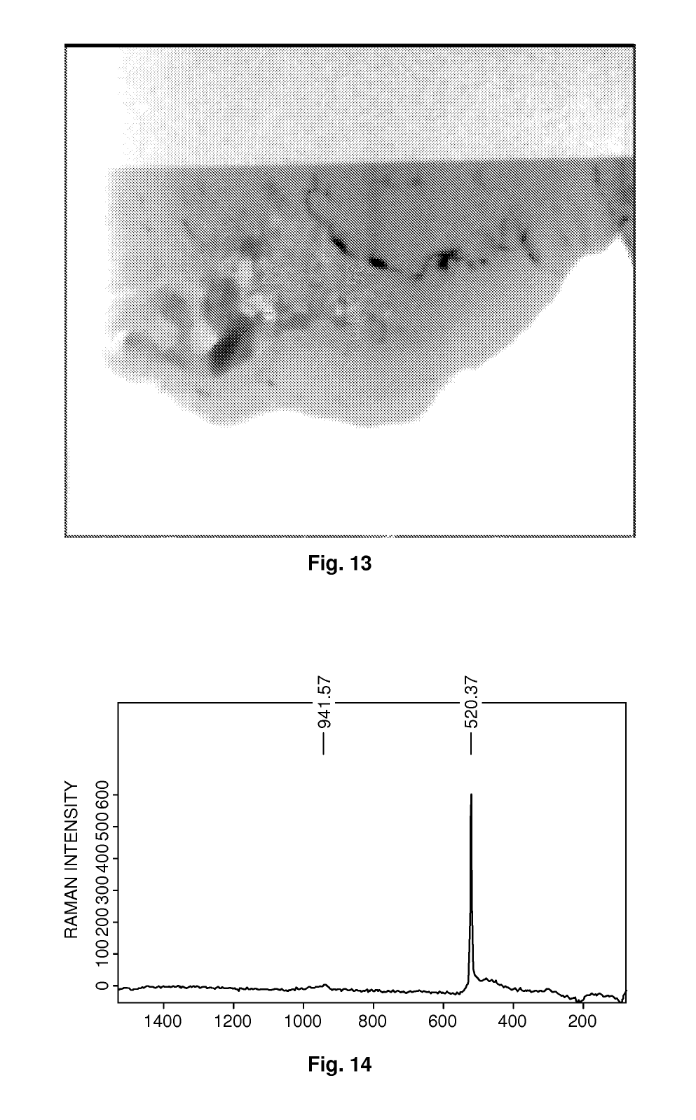

FIG. 13 illustrates an arrangement for implementing plasma immersed ion implantation.

### DETAILED DESCRIPTION OF EMBODIMENTS OF THE INVENTION

FIG. 1 is a system level illustration of an arrangement for producing a coating with the help of cold ablation. A pulsed laser beam is generated in a laser pulse generation unit 101. Laser optics 102 are used to guide the pulsed laser beam to a target 103, and to move the focal spot on the surface of the target along a track which is commonly referred to as the ablation path. The target is held in place by a target holding and/or moving unit 104. A substrate 105 is held in place, and typically also moved, by a combination of a substrate holder and moving robotics 106. The target 103, the substrate 105, and typically at least parts of the target holding and/or moving unit 104, the substrate holder and moving robotics 106, and/or the laser optics 102 are located in a reaction chamber 107, the internal atmosphere of which is controllable by a reaction atmosphere control unit 108. A typical requirement is that a relatively low density gas atmosphere, i.e. at least an industrial grade vacuum, prevails around the target and the substrate. This means that the reaction atmosphere control unit 108 must contain at least a vacuum pump, and in many cases also some controllable gas sources. One or more computers, measurement devices and the like are coupled to the controllable parts of the arrangement in order to implement a process control arrangement 109.

FIG. 2 illustrates schematically the concept of fast repeating plasma fronts. In this simplified drawing we assume that the plasma constituents move along parallel, linear trajectories from down to up. On the surface of a substrate 105, one layer of plasma constituents 201 has just hit the surface. The process of dissipating the kinetic energy of the plasma constituents through interactions with the substrate has begun, but some of the original energy of the plasma constituents still remains. At the same time the next front of plasma constituents 202 is already on its way, followed by the third front of plasma constituents 203. The successive fronts of plasma constituents originate from successive laser pulses that have hit the target so rapidly after one another that the mean time between the plasma fronts hitting the substrate 105 is shorter than a typical time constant characteristic of the process of dissipating the energy of the plasma constituents.

The crude pictorial representation used in FIG. 2 is naturally simplified in more than one way. For example, the atoms, ions, molecules, and/or other constituents of a plasma front do not propagate as a single, well-defined front, but merely as a distribution of different timings and velocities, only some portion of which are directed from the target to the direction of the substrate. For the purposes of this description we may assume, however, that if the constituent density and velocity distribution of a plasma front is considered, it has a certain spatial characteristic that may be designated as a representative time-dependent location of the plasma front and describes how a significant portion of the plasma front typically behaves.

The constituent rows in FIG. 2 may be thought to illustrate the representative time-dependent locations of the corresponding three consecutive plasma fronts.

FIG. 3 illustrates schematically a result, where throughout the area 301 on the surface of the substrate 105 the constituents that now form the coating have arranged themselves according to the repeating pattern that constitutes a crystal lattice. A major contribution to the forming of a crystalline structure came from the fact that a sufficient number of constituents resulting from a number of consecutive plasma fronts made it to form a nucleus on the surface of the substrate fast enough before the mean energy level of the constituents would have fallen so low that lattice mobility would have been impeded. The mean energy of the constituents in the nucleus thus allowed the spontaneous formation of a crystalline structure.

Nucleation processes can be classified as homogeneous and heterogeneous. Homogeneous nucleation is known to occur in a supercooled liquid phase, especially if the free energy per unit volume of a solid state of the material in question is smaller than the free energy per unit volume of the liquid state. The free energy per unit volume balances between the energy gained or consumed in a change of volume, and the energy gained or consumed in changing an interface. A hypothetical nucleus is too small, and consequently unstable, if the energy that would be released by forming its volume is not enough to create its surface. In such a case nucleation does not proceed. If interactions with other surrounding materials can be neglected, the critical stability of a nucleus is essentially determined by its radius. If the radius is above the so called critical radius of nucleation, the nucleation will proceed.

Heterogeneous nucleation is encountered more often in practice than homogeneous. Heterogeneous nucleation benefits from the presence of phase boundaries, impurities, and other distinct locations that can diminish the effective surface energy required for nucleation to initiate and proceed. However, especially if the spatial occurrence of such centres of nucleation cannot be controlled, the resulting crystallization may take place so randomly and unevenly that the surface quality of the eventual coating may become less than optimal. When evenness of the crystallization process is aimed at, homogeneous nucleation would be preferred over heterogeneous, but it may prove to be difficult to achieve the proper conditions. Later in this description we will consider certain possible ways of controlling the spatial occurrence of centres of nucleation, in order to introduce controllability to heterogeneous nucleation also.

The microscopic level appearance of the substrate surface may have an important effect on how nucleation begins and how crystallization proceeds. As an example, a silicon surface or other crystalline substrate surface may be ground with diamond paste in order to prepare nucleation centres. A primer layer can also be applied to the surface of a substrate. If the crystalline structure of the primer layer already offers suitable unit cells, these can advantageously direct the growth of the crystalline structure of the eventual coating in appropriate directions. Materials that are suitable for use as primer layers include but are not limited to iridium, rhodium, platinum, rhenium, and nickel. A burst mode cold ablation laser and an appropriate target comprising primer material can be used to produce the primer layer.

An important thing to note is that the atoms, ions, molecules and/or other constituents that form the crystalline structure are not necessarily just atoms, ions, or molecules of the original target material. If a controlled gas atmosphere has been created in a space surrounding the target and the substrate, some or all of said gas atmosphere may comprise a reactive gas, elements of which are capable of mixing into and/or reacting with constituents of the plasma. Thus the expression “constituents resulting from the plasma fronts” covers also reaction results from reactions between constituents of the target material and constituents of a reactive gas. Yet another possibility is to use two or more targets made of different materials that are cold ablated either simultaneously or in turns, so that what actually forms a coating is a mixture and/or a reaction result from two or more different target materials, and possibly also from a reactive gas. An inert gas can be used in the controlled gas atmosphere, which enables controlling the deceleration of plasma flying off the target through controlling the pressure of the controlled gas atmosphere.

FIG. 4 illustrates some factors that must be taken into account when the focal spot is scanned on the surface of the target in order to create the advantageous conditions that facilitate the process described above. The overlapping ovals in the top right part of FIG. 4 illustrate the spots on a target surface hit by ten consecutive laser pulses. In FIG. 4 we assume that the focal spot, i.e. the area on the target surface on which a majority of the optical power of a single laser pulse will be delivered, has a slightly oval form with axial diameters of approximately 25×40 μm. We also assume that a scanner in the laser optics section has been configured to move the focal spot along a linear trajectory that in FIG. 4 represents a horizontal movement from left to right.

In FIG. 4 it is additionally assumed that one laser pulse removes an even layer of 100 nm of the target material across the whole oval form of the focal spot. This requires that the power density delivered over the focal spot area exceeds the ablation threshold and is evenly distributed. Practical experiments with picoseconds lasers have shown that the ablation threshold of various materials exhibits relatively little variation in the range 0.1-2 J/cm² (joules per square centimetre), depending on factors like material type, wavelength, and pulse length in time. The depth of the void eaten out by a single picoseconds laser pulse of the kind generally used at the time of writing this description tends to be between 10 and 100 nanometres, with the focal spot diameter typically selected in the range 5-50 μm.

The overlap between successive pulses in FIG. 4 is 90% of the length of the shorter (transverse) diameter of the focal spot. The horizontal shift of the focal spot is 2.5 μm between pulses in FIG. 4. This can be achieved for example with the exemplary values of 5 m/s for scanning speed and 2 MHz for pulse repetition frequency. Since the pulse length is in the order of picoseconds, the inverse (500 ns) of the pulse repetition frequency is essentially the same as the dark time between consecutive pulses.

The graphs in the lower and left parts of FIG. 4 illustrate the (theoretical) depth profile of the crater formed on the target surface by said ten consecutive laser pulses, measured along the lines A-A and B-B respectively. It should be noted that the scale, although in micrometres, is different on the axes of said graphs; in reality the crater is very shallow compared to its width. Even so, it should also be noted that a surface roughness that involves vertical differences in the order of a micrometre is already considered very rough for many applications. For example, if a target has been already used for one round of cold ablation, and as a consequence its surface exhibits vertical differences of this order of magnitude, it is possible that using the same target again would result in fragments of the target material breaking loose and becoming mixed in the plasma. Same kind of fragment formation may take place even on the very first ablation round, if the ablation path, pulse repetition frequency, and scanning speed have not been properly optimized. Eventually some of the fragments might attach to the surface to be coated, seriously disturbing the crystallization process and resulting in suboptimal microscopic structure and surface quality of the coating.

Overlap between the hits of consecutive laser pulses can be even completely avoided, if the scanning speed is made large enough. In the example of FIG. 4, a horizontal scanning speed larger than 50 m/s would ensure that adjacent laser pulses would always hit only a virgin part of the target. However, moving the focal spot on the target is reflected as a corresponding change in the area of the substrate that will receive the plasma from the next pulse. Above we have shown that achieving the suitable conditions for forming crystalline structures in the coating requires a sufficient number of sufficiently energetic (i.e. freshly arrived) constituents of the coating material located sufficient densely on the surface of the substrate. Moving the focal spot very fast and very far between pulses tends to undermine this aim by making a significant portion of the next plasma front hit a completely new part of the substrate.

Fragmenting becomes an issue also if the target material is relatively transparent to the laser wavelength that is used. High transparency means that photons of the laser pulse may penetrate relatively deep into the target material before interacting with its atoms and molecules. This phenomenon is especially prominent with an infrared range laser focused on a target made of silicon or a compound comprising large amounts of silicon. If the sharpest focal point of the laser beam is located inside the target material, it may cause a kind of internal explosion that blows even visible size fragments off the actual surface of the target. Suboptimal surface roughness of the produced coating is then only one consequence. If the aim is to deliver the next laser pulse very quickly and in a very tightly controlled manner to the target, the randomness in which the target surface will form during the process makes it very difficult.

Another factor to be considered in the creation of a number of consecutive plasma fronts is the shading effect of the already created plasma. In principle, the plasma plume will expand into all free directions, so that from a planar target the plasma will fly evenly into the 2xpi steradian spatial angle. In micromachining applications it is customary to align the laser beam normal to the surface of the target, and to drill a hole by repeatedly applying laser pulses to the exactly same spot. As the hole gets deeper, the free angle available for the created plasma gets smaller and smaller, until eventually in the theoretical limiting case the plasma can only fly backwards along the same line from which the next laser pulse will come.

In coating applications it is advantageous to align the laser beam at an oblique angle against the target, which has been schematically illustrated e.g. in FIG. 1 above. If now a laser pulse hits a location on the target that already exhibits a crater of some kind, the local topology on the target surface tends to direct the plasma plume so that the predominant flying direction of the plasma will not coincide with the optical axis of the laser beam, but will be directed more towards the substrate. Even so, if a number of laser pulses are delivered to the target one after the other, eventually some kind of a plasma cloud will also be found on the path of the incoming radiation, which may decrease the ablation efficiency.

FIG. 5 suggests a solution that may have very advantageous effects on both the creation of closely following plasma fronts and the avoidance of plasma shading. The units on the vertical scale are of no importance in FIG. 5, because the graph illustrates mainly the time aspects of a so-called burst mode. The pulsed laser is not operated continuously but in a burst mode, in which a first burst 501 of consecutive laser pulses is focused on the target with a first delay 502 between pulses. This first delay 502 is so short that on the substrate, constituents resulting from those plasma fronts that were created by the pulses of the first burst 501 form a nucleus where a mean energy of the constituents allows the spontaneous formation of a crystalline structure. After the first burst 501 there is a second delay 503, which is longer than the first delay 502. After the second delay 503 a second burst 504 of consecutive laser pulses is focused on the target, again with the first delay between pulses. The length in time of an individual pulse is in the order of picoseconds, which means that they can be considered to constitute delta spikes on the illustrated time scale.

The delay between bursts is advantageous for many reasons. Firstly, taken the technology of laser sources known at the date of writing this description, it is much easier to achieve very fast pulse repetition rates (such as those required within a burst) if it is not required to maintain the same very fast pulse repetition rate continuously, but a longer pause is allowed between bursts. Secondly, the longer delay enables avoiding loss of optical power in the shadowing effect of plasma. The pulses of a burst may be powerful enough to ablate enough material from the target to form the nucleus on the substrate that eventually undergoes nucleation and crystallization. Especially if such powerful pulses are used, immediately after the burst the surroundings of the focal spot on the target may be so clouded with plasma that trying to continue delivering more pulses to the target would result in losing a significant part of optical power by absorption and diffraction in the plasma. Thirdly, the strategy of delivering a number of pulses very close to each other and then having a pause may help in designing the optimal ablation path, for example so that the pulses of the burst have a relatively large overlap on the target surface, but before the beginning of the next burst the focal point is moved to a virgin part of the target surface or at least significantly aside from the location where the pulses of the first burst were delivered.

As an example, we may consider using a 50 W LUMERA LASER Hyper Rapid picoseconds laser, available from LUMERA LASER GmbH, Opelstr. 10 D-67661, Kaiserslautern, Germany, as the laser pulse generation unit. The model of this laser source that is available in autumn 2009 is capable of delivering several picosecond pulses with 20 nanoseconds separation, and pulse energy in the range of 10-50 μJ. If a pulse energy of 50 μJ is used, and the target material is assumed to have an ablation threshold of 1 J/cm², the theoretical upper limit for the diameter of a circular focal spot is 78 μm, in order to surpass the ablation threshold throughout the focal spot area. In practice some pulse-energy reserves may be needed for system losses and harmonic generation, but practical focal spot sizes nevertheless have a diameter in the range of tens of micrometres.

The manufacturer has reported that in micromachining applications said laser source is capable of cold ablating material at the rate 10 mm³/min for stainless steel, 20-60 mm³/min for glass and up to 100 mm³/min for organic and biological materials when operating in burst mode. Some exemplary calculations can be made:

### Example 1

Focal spot diameter: 25 μm
Ablation depth: 100 nm
Ablation rate: 60 mm³/min
Pulses in burst: 5
Pulse separation in burst: 20 ns

If these values were to be achieved, the second delay (i.e. the dark time from the last pulse of the first burst to the first pulse of the second burst) should be 170 ns, meaning that 4×10⁶ bursts were generated per second. This value of the second delay is considered to be somewhat short, as it is assumed that the second delay should be 200 ns or more.

### Example 2

Focal spot diameter: 25 μm
Ablation depth: 100 nm
Ablation rate: 60 mm³/min
Pulses in burst: 10
Pulse separation in burst: 20 ns

If these values were to be achieved, the second delay (i.e. the dark time from the last pulse of the first burst to the first pulse of the second burst) should be 320 ns, meaning that 2×10⁶ bursts were generated per second.

### Example 3

Focal spot diameter: 50 μm
Ablation depth: 100 nm
Pulses in burst: 5
Pulse separation in burst: 20 ns

If these values were to be achieved, the second delay (i.e. the dark time from the last pulse of the first burst to the first pulse of the second burst) should be 900 ns, meaning that 1.02×10⁶ bursts were generated per second.

Exactly how close to each other the pulses must follow within a burst is a design parameter that depends on e.g. the selection of the target and substrate materials, distance between the target and the substrate, pulse energy, focal point size, as well as on the constitution and pressure of the gas atmosphere surrounding the target and the substrate. Currently it is assumed that the delay between pulses within a burst should be less than 200 ns, and preferably 20 ns, or less. The calculational examples above show that corresponding second delay values are typically between 200 and 2000 ns.

If we assume the same scanning speed as in the example of FIG. 4, i.e. 5 m/s, the five pulses that constitute a burst with 20 ns intervals will fall essentially on the same spot on the target: the focal spot only moves 400 nm between the first and the last pulse of the burst. However, if the separation between bursts is not more than 1000 ns, a constant scanning speed of 5 m/s would mean that from the beginning of one burst to the beginning of the next burst the focal spot would not move more than 5 μm, resulting in heavy overlap between the burst craters. While certainly desirable in micromachining, such a large overlap is hardly desirable if the aim is to produce good-quality fragment-free plasma for coating purposes, because the surface roughness of the target would quickly increase to even tens of micrometres and increase the risk of fragmenting. It is foreseen that coating applications will call for significantly higher scanning speeds, which may not be achievable with galvo heads or wobbler-type scanners, because the inertia of the moving parts would become too large. Scanning speeds of sufficient magnitude are routinely achieved with turbine scanners, in which the reflective surfaces that divert the laser beam are side surfaces of a polygonal prism that rotates around an axis that is perpendicular to its top and bottom surfaces.

The number of pulses in a burst deserves some consideration. Obviously, the limiting minimum number of pulses in burst is one, although it might be clearer to say two, because regular “bursts” of a single pulse represent nothing more than just a normal, previously known picosecond laser. However, having a steady, constant number of pulses in every burst is not a prerequisite of the invention, but different bursts may have different numbers of pulses. At the time of writing this description it is assumed that bursts should have 1-10 pulses per burst, although the possibility of having as many as 50 pulses per burst is not excluded either.

Assuming that the pulses that belong to a common burst come in a cycle fast enough to allow constituents resulting from a number of consecutive plasma fronts nucleate and crystallize, we may conclude that by controlling the number of pulses per burst in relation to the delay between bursts it is possible to control the amount of matter that takes part in each nucleation and crystallization round. Also it must be noted that although cold ablation is “cold” by definition, the larger amounts of plasma are considered, the closer the thermodynamic system becomes a situation where a relatively high macroscopic temperature could be said to locally exist. Many materials that can be used in coatings (like diamond, for example) exhibit metastable states, which will not survive high macroscopic temperatures. In order to create enough plasma constituents in metastable states to enable nucleation and crystallization, but to simultaneously keep said plasma constituents from being destroyed, it may be advantageous to have a delay between a number of closely following laser pulses, i.e. to use the laser in burst mode. In such applications, selecting the number of pulses per burst can be done experimentally, by observing the occurrence of coating results that are known to result from the metastable states, and changing the number of pulses per burst and/or delay between bursts until the observed occurrence of said coating results achieves a maximum.

It should be noted that making the laser pulses come with shorter intervals between successive pulses, i.e. using a burst mode, is not the only possible way of affecting plasma density (which, in turn, is important in enabling nucleation and crystallization). Other means for increasing plasma density include for example selecting the geometry of the reaction area appropriately. Since plasma flies off the target to essentially all free directions, density of constituents in the plasma plume is roughly inversely proportional to distance from the target. By placing the substrate close enough to the target the density of the constituents arriving on the substrate can be increased. All factors that have an influence on plasma density are process parameters, and only proper optimization of all process parameters as a whole will maximize the results in the form of desired properties of the coating.

Above we have considered producing crystalline structures in the coating only from the viewpoint of delivering enough constituents of sufficient energy level fast enough to the surface of the substrate. While this principle is important to the present invention, it does not exclude using other methods simultaneously or separately that aid or support the formation of said structures. Above it has already been mentioned that the controlled gas atmosphere may have a significant part to play, in the form of bringing a reactive gas as a reactant to the process of producing the coating, and/or in the form of enabling controlling the deceleration of the plasma between the target and the substrate. When the plasma constituents interact with the gas that they encounter on their way, a nucleation process may begin that produces nuclei on the fly. These attach to the substrate surface and continue to act as the centres from which crystal growth continues until the mean energy level of the constituents of the coating decreases below the limit at which mobility in the lattice ceases to exist. The effect of the gas atmosphere in stimulating the formation of crystalline structures can be controlled by selecting the species of gas and controlling their partial pressures, as well as the overall temperature of the process.

Another class of embodiments that can be used to aid or support the formation of crystalline structures comprises subjecting constituents on the surface of said substrate, that result from the consecutive plasma fronts, to one or more bursts of optical radiation. This causes a kind of annealing of the coating formed by said constituents. A subgenus of optically assisted crystal formation is called flash lamp annealing, an application of which is described in the following in association with FIG. 6.

FIG. 6 is a schematic illustration of an arrangement in which two-sided coating of a continuous substrate web is possible. Substrate handling takes place by a so-called roll to roll method, in which the uncoated substrate comes from an input roll 601 and after the coating process the coated substrate is rolled onto an output roll 602. The width of the substrate web can be several decimetres, e.g. 30 cm, or even a metre or more. FIG. 6 can be understood as a top view, so that in the actual apparatus the axes of rotation of the rolls 601 and 602 are vertical. A similar handling geometry, i.e. a planar substrate oriented as a vertical plane and moved in one direction through the coating phase, can naturally be applied also with rigid substrates like glass panes or the like that are not suitable for winding onto rolls.

The coating takes place in a reaction chamber 107 which has shutters 603 at the substrate input and output slits for closing the reaction chamber tightly enough to enable creating a controlled gas atmosphere. For the last-mentioned purpose the arrangement comprises also the reaction atmosphere control unit 108. The arrangement comprises two laser pulse generation units 101, one on each side of the substrate, as well as the corresponding laser optics 102. Targets 103 are also held in place (and potentially moved) on each side of the substrate. In order to illustrate the wide applicability of different kinds of target holding and/or moving units, FIG. 6 assumes that the targets are located on the cylindrical surfaces of vertically assembled target rolls that extend essentially as far in the vertical direction as the width of the substrate web. Different target configurations and/or target materials can be used on different sides of the substrate; or only one surface of the substrate could be coated so that the parts 101, 102, and 103 would only be needed on that side; or other kinds of differences to the exemplary configuration of FIG. 6 could be presented.

The flash lamp annealing of the coating takes place later in the same reaction chamber in the example of FIG. 6. On each side of the substrate web there is a source 604 of optical radiation, implemented for example in the form of a xenon flash lamp. The intensity of the optical radiation used for the flash lamp annealing of coatings is typically in the order of some J/cm², delivered in one or several bursts per an area where crystallization should be enhanced. In a process like that of FIG. 6, which enables a continuous or stepwise movement of the substrate, selectable parameters of the flash lamp annealing stage include (but are not limited to) the flashing frequency versus substrate moving speed; number and location of the flash lamp(s); distance between the coated surface and the flash lamp(s); time difference between applying the coating and subjecting it to flash lamp annealing; the intensity of the optical radiation delivered in each flash onto the coating; and the wavelength distribution of the optical radiation produced in the flash.

In FIG. 6 the flash lamp annealing takes place in the same reaction chamber as the cold ablation, but as a different process step, with even some web controlling rolls separating the two steps. The annealing step could be made even very much later in the process, so that e.g. the substrate is rolled again after coating and transferred to a separate annealing arrangement. On the other hand, the annealing step could be brought even into the same process step with the cold ablation, so that the bursts of annealing optical radiation would be delivered simultaneously or only very little after the delivery of laser pulses, in which last-mentioned case the additional energy brought to the coating constituents by the optical radiation would have a part to play even in the original formation of the crystalline structures.

Another way of utilizing optical radiation for annealing is known as laser annealing. It comprises treating a formed coating with laser radiation, which can be continuous or delivered in highly energetic pulses. The aim is to make the coating absorb enough of the energy of the laser radiation and convert it into energy of the constituents of the coating, so that at least locally the mean energy level of the constituents of the coating rises high enough to allow lattice mobility. In a coating process where cold ablation was originally used for producing the coating, laser annealing may employ a separate annealing laser that is configured to scan the coated surface of the substrate. Such a separate annealing laser may be a picosecond laser, but because this time heating the surface hit by the laser is to be achieved rather than avoided, it can also be a nanosecond laser or other kind of laser. Annealing lasers are schematically represented in FIG. 6 with the reference designator 605.

Alternatively (or even additionally) the same laser could be used both for the cold ablation phase and the laser annealing phase, for example so that the scanning geometry is controllably changed to make the laser scan the coated surface of the substrate instead of the target, and simultaneously the delivered power density per pulse is lowered so that the result is an annealing effect on the coating rather than new ablation of material off the coating. Lowering the power density may be achieved in various ways, including but not being limited to increasing focal spot size; changing the incident angle at which the laser hits the surface; tuning the power setting of the laser; and using a divider that divides the incident laser beam to multiple locations on the coated surface of the substrate instead of just one (or a few) locations on the target.

Lasers known at the time of writing this description allow controlling the effective depth, at which most absorption occurs in the surface hit by the laser, with an accuracy as good as 10 nanometres. As a consequence, laser annealing can well be performed for coatings formed on thermally sensitive substrates, because the absorption of energy can be effectively limited to the coating, without causing significant heating and its associated unwanted effects in the substrate.

Other forms of annealing that can be combined with the production of a coating with cold ablation include, but are not limited to, subjecting the nuclei and/or crystalline structures to microwaves, from which energy is absorbed into the coating; bombarding the coating with ions; and subjecting the coating to a flow of plasma from some other source than the primary target from which the material of the coating originally came from.

FIG. 7 is a systematic flow diagram representation of a method for producing a coating on a substrate according to an embodiment of the invention. Not all steps illustrated in FIG. 7 are essential to the invention. Step 701 represents placing the substrate adjacent to a target, and step 702 represents creating a controlled gas atmosphere in a space surrounding said target and said substrate. Step 703 represents cold ablating material off the target by focusing a number of consecutive laser pulses on the target, thus producing a number of consecutive plasma fronts that move at least partly to the direction of said substrate. The time difference between said consecutive laser pulses is so short that on said substrate, constituents resulting from a number of consecutive plasma fronts form a nucleus where a mean energy of said constituents allows the spontaneous formation of a crystalline structure.

According to steps 705 and 706, step 703 may involve a repeated cycle of two substeps. Substep 705 represents focusing a first burst of consecutive laser pulses on the target with a first delay between pulses that is so short that on said substrate, constituents resulting from a number of consecutive plasma fronts form a nucleus where a mean energy of said constituents allows the spontaneous formation of a crystalline structure. Step 706 represents waiting for a second delay, which is longer than said first delay, before focusing a second burst of consecutive laser pulses on the target with the first delay between pulses.

Step 704 represents subjecting constituents on the surface of said substrate, that result from said consecutive plasma fronts, to one or more bursts of optical radiation for annealing the coating formed by said constituents.

The coating process is typically controlled by a programmable control apparatus, i.e. a computer. FIG. 7 can also be understood as representing a computer program product comprising machine-readable instructions that, when executed on a processor, cause the implementation of the corresponding method steps.

FIG. 8 illustrates an arrangement for producing particles with crystalline structure. The arrangement differs from an arrangement for producing a coating in that a substrate is not needed, but the arrangement comprises a particle collector unit 801 configured to collect crystalline particles produced by the arrangement. A target holding unit 104 is configured to hold a target 103 in place, and a laser pulse generation unit 101 is configured to generate a pulsed laser beam capable of cold ablating the material of said target 103. Just like in the coating arrangements, laser optics 102 are configured to guide the pulsed laser beam to said target 103 for producing a number of consecutive plasma fronts that in this case move into a wide range of directions away from the target. The laser pulse generation unit 101 is configured to use a time difference between consecutive laser pulses that is so short that in the reaction space located off the target, constituents resulting from a number of consecutive plasma fronts form nuclei where a mean energy of said constituents allows the spontaneous formation of crystalline structures.

Also in this case it is possible to aid the crystallization of the flying particles with optical annealing. As an example, FIG. 8 illustrates schematically a source 604 of optical radiation. Bursts of optical radiation are emitted by said source 604, and directed towards the flying particles. Absorption of energy from said optical radiation raises the local temperature in the flying particles, or at least helps to lengthen the period of time during which the mean energy level within a nucleus is high enough to allow the formation of a crystalline structure.

The pressure and constitution of the controlled gas atmosphere that surrounds the target has an important effect on the formation of nuclei and crystallizing particles. A higher pressure of the gaseous medium through which the plasma flies means more collisions between constituents of the plasma, which typically speeds up nucleation. Atoms or molecules of the gaseous medium can even act as nucleation centres for heterogeneous nucleation, and/or react with the plasma constituents in order to form crystalline particles that contain more than just the material of the original target. The medium in which crystallization occurs does not need to be gaseous, but it can also be in liquid phase. The structure and operation of the particle collector unit 801 is not important to the present invention; from the field of other technologies that are used to produce nano- and microparticles there are known numerous possible ways of implementing the particle collection function.

A certain cross-breed between the principles illustrated in FIGS. 1 and 8 is an arrangement in which the constituents of the flying plasma make it to nucleation and crystallization already when flying, but they nevertheless hit the surface of a substrate and form a kind of a coating. In such cases the meaning may be to produce a coating that comprises distinctive nanoparticles and consequently has a certain desired surface roughness; for example in implants that should come into contact with and grow together with living tissue it has been found that a surface roughness in the order of 50 nanometres may stimulate the attaching of tissue cells to the surface of the implant. Another meaning may be to use the substrate simply as a way to collect the crystallized nanoparticles, so that at some later step of the process they are made to fall out of the surface of the substrate for delivery to an output.

Independent of whether the purpose is to produce a coating or crystalline particles, deliberately providing nucleation centres to the plasma plume and/or to the substrate surface may have advantageous effects in offering a way to control the nucleation process. Various ways exist for such deliberate provision of nucleation centres. FIG. 9 illustrates the use of a doped target 901, in which a matrix of the actual target material comprises a selected amount of atoms, ions and/or molecules 902 of a different substance mixed therein. A laser pulse 903 causes cold ablation, during which a plasma plume 904 is created, the constituents of which are both atoms, ions, and/or molecules of the actual target material and atoms, ions, or molecules of the doping substance that act as nucleation centres. The concentration of the dopant does not need to be constant in the target, but a variable dopant concentration can be used to affect the way in which the nucleation centres are generated. For example, there can be only a very thin layer of doped matter on the surface of the target, so that after the initial phase of the process where the very surface layer of the target has been eaten away, no more nucleation centres are deliberately provided in the plasma plume.

FIG. 10 illustrates the use of a composite target 1001, which comprises a first region 1002 of an actual target material and a second region 1003 of a material that is to provide the nucleation centres. These regions may be parts of a single mechanical piece, or they may appear in completely separate mechanical pieces. Laser pulses 1004 and 1005 are separately focused on each of said first and second regions, causing cold ablation in both so that the result is a primary plasma plume 1006 the constituents of which are atoms, ions, and/or molecules of the actual target material, as well as a secondary plasma plume the constituents of which are atoms, ions, or molecules 1007 of the substance that acts as the provider of nucleation centres. Composite targets are especially useful if a coating or crystalline particles should consist of a combination semiconductor, such as gallium arsenide or other, more complicated combinations. It may not be easy to manufacture a single target that would consist of the desired combination, but it may be well possible to manufacture different targets or target regions that consist of the component materials of the combination.

Another application where composite targets are useful is the production of a coating that consists of a doped semiconductor or layers of differently doped semiconductors, because in that case the bulk semiconductor may come from a first target (or target region) and the dopant(s) may come from its or their own targets or target regions. By controlling the delivery of laser pulses to the different targets or target regions in different phases of the coating process, it may be possible to manufacture a complicated layered structure with different dopings in different layers in a single cold ablation process, without the need to open the reaction chamber at all during the process.

FIG. 11 illustrates the principle using two parallel laser pulse generation units 101, each equipped with its own laser optics 102, each focusing the laser pulses to a different target 103 (or different part of the same target, e.g. a composite target like the one illustrated in FIG. 10). Such a configuration allows a large freedom to separately control the laser pulse characteristics delivered to each target (or each part of the target), for example so that the characteristics of the laser pulses from a first laser pulse generation unit are optimised for cold ablation in the actual target material, and the characteristics of the laser pulses from a second laser pulse generation unit are optimised for cold ablation in the substance that acts as the provider of nucleation centres. The laser parameters than can be separately controlled include, but are not limited to, laser wavelength, pulse duration, pulse power, focal spot size, number of pulses per burst, separation in time between consecutive pulses in a burst, and separation in time between consecutive bursts. Accurately controlling the delivery of pulses from two separate sources allows also very accurate control over the relative timing and intensity at which there occur fronts of nucleation centres and fronts of plasma constituents from the actual coating material.

FIG. 12 illustrates the principle of using a single laser pulse generation unit 101, but a specific kind of laser optics 1202, which are configured to separately deliver laser pulses to different targets 103 (or different parts of the same target, e.g. a composite target like the one illustrated in FIG. 10). The length of the optical path to each of the separate targets (or parts of target) may be the same, or it may be deliberately different, causing the laser pulses to arrive at different times to the different targets. The laser optics 1202 may even be arranged to gate the laser pulses so that not all laser pulses that hit the first target hit also the second target, or vice versa. This configuration has the advantage that the delivery of laser pulses to each of the targets (or target parts) may be very precisely synchronized, because they come from the same source and there is not necessarily any other difference between delivery to different targets than the difference in optical path.

What has been said of two targets and/or two materials in the target in association with FIGS. 9, 10, 11, and 12, can naturally be easily generalized to three or more targets and/or three or more materials in the target. Many kinds of combinations are possible, e.g. having one target of pure single target material, another target made of doped material, and yet another target which is a composite target.

### Example

### Nanocrystalline Silicon on a Silicon Substrate

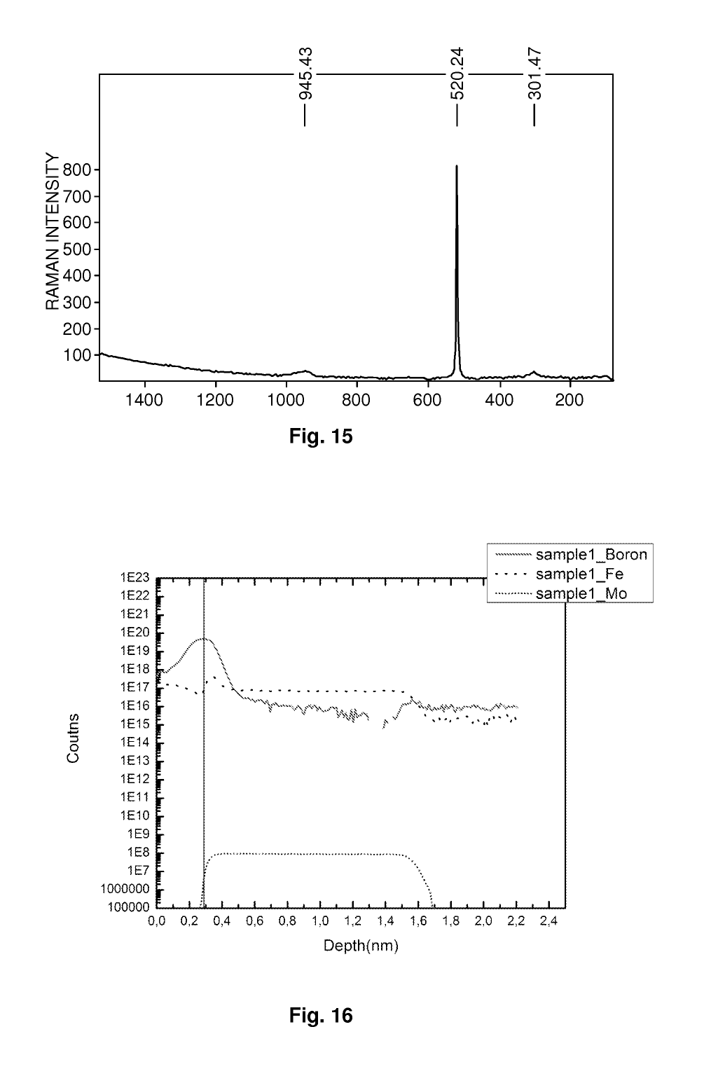

FIG. 13 shows a transmission electron microscopy (TEM) image of a boron doped silicon thin film that was manufactured on a silicon substrate using a 50 W LUMERA Hyper Rapid picosecond laser with burst mode. The coating was manufactured at a 5×10⁻⁷ mbar pressure with no added gaseous medium in the chamber. The image features clearly the nanocrystalline nature of the deposited silicon film, which is further confirmed by the IR Raman analysis as represented in FIG. 14. It can be compared to the pure, crystalline silicon IR Raman spectrum represented in FIG. 15. Raman spectroscopy is a well-known and widely used method for this kind of characterization (see e.g. O. Vetterl et al.: “Preparation of microcrystalline silicon seed-layers with defined structural properties”, Thin Solid Films 427, 2003, pp. 46-50). The crystalline structure can be further confirmed through XRD analysis of the spectra, which show the typical broadened peaks characteristic for nanocrystalline Si material.

The deposition was carried out at room temperature by focusing the IR-wavelength (1064 nm) laser pulses in a 45-degree angle onto a boron doped silicon target manufactured by Okmetic Oyj. The boron concentration in the target was 2×10⁻¹⁸. The laser pulses were scanned across the target along a 70 mm wide line, with controlled relative overlapping between the pulses in both x and y directions. The size of the focal spot was about 30 micrometres in diameter, and the target-substrate distance was kept at 30 mm. The deposition time was five minutes. In its normal operating mode, the LUMERA Hyper Rapid produces an average power of 50 watts. In burst mode, the pulses in the bursts are repeated at 50 MHz and the average power is higher. For the sample described here, the bursts had 5 pulses each and the bursts were repeated at 500 kHz. In addition, 50% of the maximum power of the laser was used. This means that the output energies are >25 μJ/burst and >5 μJ/pulse, omitting the losses caused by the optics. The total transmissivity of the optical system and beam delivery path is around 50%.

The deposition of (nano)crystalline silicon films with burst mode is not restricted to using the IR wavelength of the laser, but similar crystalline silicon films were also deposited utilizing burst mode at the green wavelength (532 nm). Moreover, crystalline silicon films were deposited on stainless steel substrates utilizing burst mode both at IR and green wavelengths. The original boron doping level (2×10⁻¹⁸) of the silicon target was preserved in the deposited films. One exemplary SIMS (Secondary Ion Mass Spectrometry) analysis describing the boron content of a boron doped (2×10⁻¹⁸) silicon film deposited on a stainless steel substrate is shown in FIG. 16.

By adjusting the number of pulses in each burst and other parameters like plasma fluence (mostly affected by target-to-sample distance) it was possible to fine tune the size and amount of crystals in the silicon films as evidenced by the XRD and Raman measurements. If an amorphous silicon layer is deposited on this burst-deposited crystalline film, the crystals in the burst-deposited silicon effectively act as nucleation sites for crystal growth during a subsequent heat treatment in a furnace or flash annealing stage to produce thick crystalline films.

### Example

### Nanocrystalline Niobium on a Glass Substrate

Room temperature deposition of a niobium film on a glass substrate was carried out with a 50 W LUMERA Hyper Rapid picosecond laser at a pressure of 1.5×10⁻⁶ mbar. IR-wavelength (1064 nm) laser pulses were focused in a 60-degree angle onto a metallic niobium target and scanned across its surface with a scanning width of 80 mm, with controlled relative overlapping between the pulses in both x and y directions. The size of the focal spot was about 30 μm in diameter, and the target-substrate distance was kept at 15 mm. The deposition time was 13 minutes. For the sample described here, the bursts had 10 pulses each and the bursts were repeated at 1 MHz. In addition, 33% of the maximum power of the laser was used. This means that the output energies were around 16.5 μJ/burst.

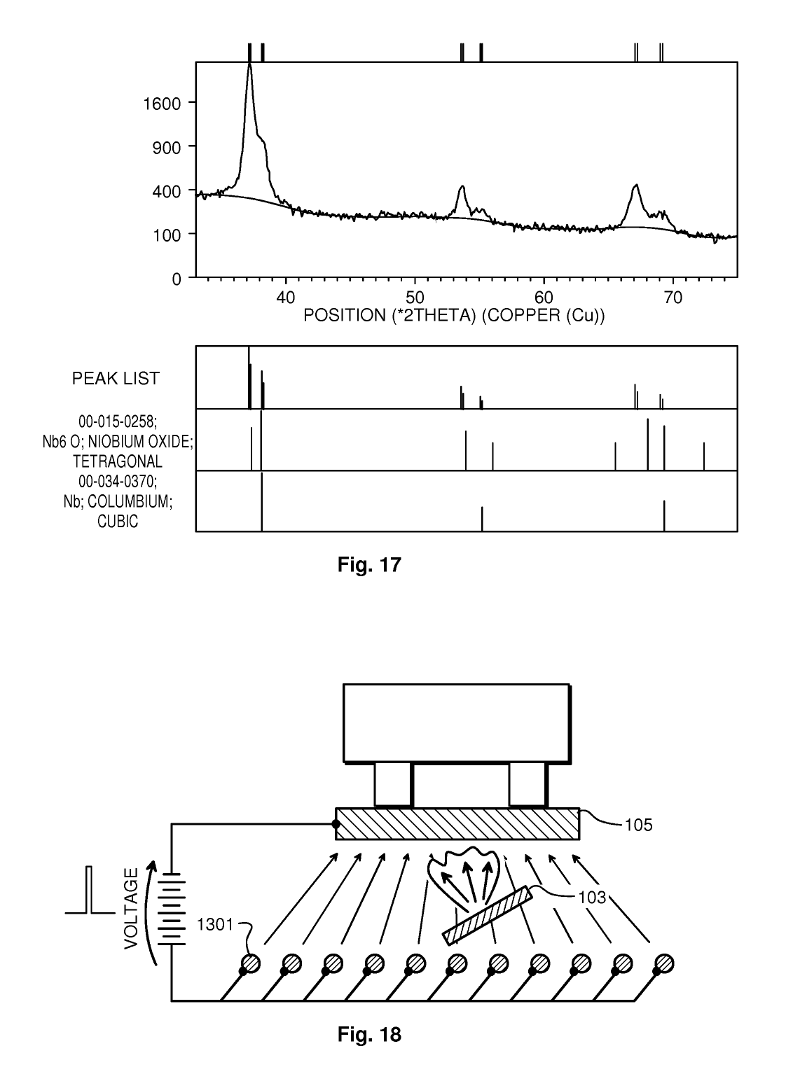

The crystalline structure of the produced niobium film was confirmed with XRD analysis. The spectrum in FIG. 17 shows clear peaks related to nanocrystalline Nb. In addition to pure Nb, minor peaks are due to oxide contamination that results from the relatively modest vacuum conditions.

### Example

### Nanocrystalline Alumina on a Glass Substrate

Room temperature deposition of an aluminium oxide film on a glass substrate was carried out with a 50 W LUMERA Hyper Rapid picosecond laser at a pressure of 5.8×10⁻⁶ mbar. IR-wavelength (1064 nm) laser pulses were focused in a 55-degree angle on a ceramic aluminium oxide target and scanned across its surface with a scanning width of 80 mm, with controlled relative overlapping between the pulses in both x and y directions. No additional oxygen or any other gas was used during the deposition. The size of the focal spot was about 30 μm in diameter, and the target-substrate distance was kept at 10 mm. The deposition time was 32 minutes. For the sample described here, the bursts had 10 pulses each and the bursts were repeated at 1 MHz. In addition, 40% of the maximum power of the laser was used. This means that the output energies were around 20 μJ/burst. The crystallinity of the produced aluminium oxide film was studied through XRD analysis, which revealed nucleation of very small nanocrystals. The fact that no additional oxygen atmosphere was used during the deposition is interesting, because it shows that the aluminium oxide target can be used as it is to produce an aluminium oxide coating.

### Further Considerations

FIG. 13 illustrates yet another principle that can be combined with cold ablation with a burst mode laser in order to facilitate making a better surface of a coating. The principle of using a DC or AC electromagnetic field to accelerate at least some constituents of plasma on their way to the substrate is generally known. One embodiment, particularly applied on radio frequencies, is Plasma Immersion Ion Implantation (PIII). The arrangement comprises a first electrode, which in FIG. 13 consists of a grid of wires 1301 located behind the target 103, and a second electrode, which in FIG. 13 is the substrate 105 that is to be coated. The geometry of the electrodes is such that if an electric field is created by coupling a voltage of suitable polarity between the electrodes, those of the plasma constituents that have an electric charge of the appropriate sign will be accelerated towards the substrate 105. In FIG. 13 the geometry is particularly such that the field lines of said electric field are at their densest close to the substrate 105, which means that the appropriately charged constituents of the plasma will experience an accelerating force that is the stronger the closer said constituents are the substrate 105.

An advantage that can be gained by combining PIII to the coating process is the better evenness of the coating in case of non-planar substrates. If the substrate surface has some macroscopic topology like dents or holes, the edges and bent surfaces of these may be more evenly coated with the help of the electric field accelerating the desired constituents of the plasma. It should be noted that since the electric field affects similarly all charged bodies, also ions of the surrounding gas atmosphere—if such are present—will be drawn to the substrate surface by the electric field. This effect can be utilized in designing the actual composition of various materials that will constitute the eventual coating.

Since the ablating laser comes in pulses, and consequently the resulting plasma comes as distinct fronts, it is not necessary to have the accelerating PIII voltage constantly on. It is sufficient to apply a very short accelerating PIII voltage pulse every time when one is needed; typically at exactly the moment when a plasma plume has been created. The pulsed nature of the accelerating PIII voltage is illustrated schematically in the far left part of FIG. 13. Repeating the voltage pulses in synchronism with the pulsed cold ablating laser means that in practice the accelerating PIII voltage is an AC voltage of suitable amplitude, frequency, and phase. The AC nature of the accelerating PIII voltage means also that the substrate does not need to be of conductive material, because the internal polarization that takes place in a dielectric substrate can be utilized to create a net electric charge of appropriate sign and magnitude to appear on that surface of the substrate that should be coated.

A large range of changes and modifications can be made to the features of the exemplary embodiments of the invention described so far, without departing from the scope of protection defined by the appended claims. For example, a coating consisting of a plurality of materials, or a coating on a wide substrate, can be made by guiding the laser pulses through a turbine scanner where not all reflecting side surfaces of the rotating prism are at the same angle with respect to the rotating axis of the prism. Each differently oriented side surface can reflect the laser pulses to a different target. If more than one laser source is used with the same turbine scanner, a wide variety of target and substrate geometries can be covered.

A coating is not necessarily just a single layer on a surface, but may comprise a multitude of layers stacked together for different purposes. As an example, closest to the substrate surface may be a primer layer, the purpose of which includes at least one of ensuring good attachment, offering nucleation centres, offering suitable crystalline cell structure and orientation, and stopping diffusion between the substrate and coating materials. Diffusion barrier layers and other intermediate layers may be used also between other functional layers of a stacked coating. Some of the layers of a stacked coating may have e.g. some desired electromagnetic properties, while others may be optimised for mechanical strength, outer appearance, non-stick characteristic, or others.

Aiming to produce a crystalline coating layer of considerable thickness involves the risk of invoking columnar growth, which means that a crystal does not grow neatly in the plane of the surface to be coated, but forms a column or cliff that protrudes out of the otherwise smooth surface. Columnar growth can be reduced for example so that the coating is made to consist of alternating crystalline and amorphous component layers. With the help of the present invention this is particularly easy, because a crystalline component layer can be produced by using the cold ablating laser in burst mode, and after that an amorphous component layer can be produced, even using exactly the same target, simply by turning the burst mode off or reducing the number of pulses per burst to one (or, more generally, to a number that is so small that the crystallization-enhancing effect of fast consecutive laser pulses is not observed any more in any significant magnitude).

Above the description also assumed, for the purpose of graphical clarity, that the substrate surface to be coated is planar. This is not a requirement of the invention, because firstly the constituents resulting from the plasma fronts can reach the details of also non-planar substrate surfaces, and secondly the substrate moving robotics may be utilised to rotate an arbitrary substrate so that in turn, all surfaces that are to receive a coating are suitably close to the target. Robotics are at their simplest with substrates that are planar to start with or the geometrical appearance of which can be reduced to a plane with a simple moving strategy: for example, if a cylindrical substrate is rotated around its axis of cylindrical symmetry, the outer surface is effectively reduced to a plane.

Concerning the controlled gas atmosphere, one of the advantages of cold ablation is that the target and substrate can be placed very close to each other, because neither of them is necessarily heated excessively. The distance between target and substrate has a significant role in how the plasma flies from one to the other, for example because if there is gas therebetween, the interaction between the plasma and the gas slow down the plasma. In a limiting case it is possible to do cold ablation in ambient air, because the plasma only needs to fly such a short distance that specific atmospheric conditions are not needed. Gases that are suitable constituents of a controlled gas atmosphere are, among others, helium and argon (if an inert gas atmosphere is wanted) and oxygen (if the gas atmosphere should have a reactive property).

1-30. (canceled)

31. A method for producing a coating on a substrate, comprising:
placing the substrate adjacent to a target,
cold ablating material off the target by focusing a number of consecutive laser pulses on the target, thus producing a number of consecutive plasma fronts that move at least partly to the direction of said substrate, and
scanning the focal spot of said laser pulses on the surface of the target;
wherein the time difference between said consecutive laser pulses is so short that on said substrate, constituents resulting from a number of consecutive plasma fronts form a nucleus where a mean energy of said constituents allows the spontaneous formation of a crystalline structure.

32. A method according to claim 31, comprising:
focusing a first burst of consecutive laser pulses on the target with a first delay between pulses that is so short that on said substrate, constituents resulting from a number of consecutive plasma fronts form a nucleus where a mean energy of said constituents allows the spontaneous formation of a crystalline structure, and
waiting for a second delay, which is longer than said first delay, before focusing a second burst of consecutive laser pulses on the target with the first delay between pulses.

33. A method according to claim 32, wherein the first delay is shorter than 200 nanoseconds and the second delay is longer than 200 nanoseconds.

34. A method according to claim 33, wherein the first delay is essentially 20 nanoseconds and the second delay is between 200 and 2000 nanoseconds.

35. A method according to claim 31, comprising:
creating a controlled gas atmosphere in a space surrounding said target and said substrate.

36. A method according to claim 35, wherein said controlled gas atmosphere comprises a reactive gas, and wherein said constituents resulting from said plasma fronts comprise reaction results between constituents of the target material and constituents of said reactive gas.

37. A method according to claim 35, wherein said controlled gas atmosphere comprises an inert gas, and the method comprises controlling the deceleration of plasma flying off the target through controlling the pressure of said controlled gas atmosphere.

38. A method according to claim 31, comprising:
subjecting constituents on said substrate, that result from said consecutive plasma fronts, to one or more bursts of optical radiation for annealing the coating formed by said constituents.

39. A method according to claim 38, wherein optical radiation is delivered on the coating in a separate processing step, after the substrate has been removed from the vicinity of the target.

40. A method according to claim 38, wherein optical radiation is delivered on the coating in the same space where said cold ablating is performed, so that said annealing forms a combined method step together with said cold ablating.

41. A method according to claim 31, comprising:
cold ablating first material off a first target by focusing a number of consecutive laser pulses on the first target, and
cold ablating second material off a second target by focusing a number of consecutive laser pulses on the second target.

42. A method according to claim 41, wherein plasma constituents resulting from the first material act as nucleation centres, at which nuclei of the second material are formed.

43. A method according to claim 41, wherein two separate laser pulse generation units are used, each generating laser pulses for cold ablating one target.

44. A method according to claim 41, wherein a single laser pulse generation unit is used, and beam splitting optics are utilized to provide laser pulses to said first and second targets.

45. A method according to 31, comprising:
cold ablating first and second materials off a common target that comprises said second material doped with said first material.

46. A method according to claim 45, wherein plasma constituents resulting from the first material act as nucleation centres, at which nuclei of the second material are formed.

47. An arrangement for producing a coating on a substrate, comprising:
a target holding unit (104) configured to hold a target (103) in place,
substrate holder and moving robotics (106) configured to hold in place and move a substrate (105) adjacent to said target (103),
a laser pulse generation unit (101) configured to generate a pulsed laser beam capable of cold ablating the material of said target (103), and
laser optics (102) configured to guide the pulsed laser beam to said target (103) for producing a number of consecutive plasma fronts that move at least partly to the direction of said substrate and configured to scan the focal spot of said laser pulses on the surface of the target;
characterized in that the laser pulse generation unit (101) is configured to use a time difference between consecutive laser pulses that is so short that on said substrate (105), constituents (201, 202, 203) resulting from a number of consecutive plasma fronts form a nucleus where a mean energy of said constituents allows the spontaneous formation of a crystalline structure.

48. An arrangement according to claim 47, characterized in that said laser pulse generation unit (101) and said laser optics (102) are configured to focus a first burst of consecutive laser pulses on the target (103) with a first delay between pulses that is so short that on said substrate (105), constituents (201, 202, 203) resulting from a number of consecutive plasma fronts form a nucleus where a mean energy of said constituents allows the spontaneous formation of a crystalline structure, and to wait for a second delay, which is longer than said first delay, before focusing a second burst of consecutive laser pulses on the target with the first delay between pulses.

49. An arrangement according to claim 48, characterized in that the first delay is shorter than 200 nanoseconds and the second delay is longer than 200 nanoseconds.

50. An arrangement according to claim 49, characterized in that the first delay is essentially 20 nanoseconds and the second delay is between 200 and 2000 nanoseconds.

51. An arrangement according to claim 47, characterized in that the arrangement comprises a reaction chamber (107) and a reaction atmosphere control unit (108) configured to create a controlled gas atmosphere in a space surrounding said target (103) and said substrate (105).

52. An arrangement according to claim 47, characterized in that the arrangement comprises a source (604) of optical radiation configured to subject constituents on said substrate, that result from the consecutive plasma fronts, to one or more bursts of optical radiation for annealing the coating formed by said constituents.

53. An arrangement according to claim 47, characterized in that the arrangement comprises:
a first target comprising a first material,
a second target comprising a second material, and
means for focusing a number of consecutive laser pulses on the first and second targets.

54. An arrangement according to claim 53, characterized in that said means for focusing a number of consecutive laser pulses on the first and second targets comprise two separate laser pulse generation units, each configured to generate laser pulses for cold ablating one target.

55. An arrangement according to claim 53, characterized in that said means for focusing a number of consecutive laser pulses on the first and second targets comprise a single laser pulse generation unit and beam splitting optics configured to provide laser pulses to said first and second targets.

56. An arrangement according to claim 47, characterized in that the arrangement comprises a doped target made of a second material and doped with a first material.

57. A coating produced in a process that comprises:
placing a substrate adjacent to a target, and
cold ablating material off the target by focusing a number of consecutive laser pulses on the target, thus producing a number of consecutive plasma fronts that move at least partly to the direction of said substrate, and scanning the focal spot of said laser pulses on the surface of the target;
wherein the time difference between said consecutive laser pulses is so short that on said substrate, constituents resulting from a number of consecutive plasma fronts form a nucleus where a mean energy of said constituents allows the spontaneous formation of a crystalline structure.

58. A product produced in a process that comprises:
placing a body of said product adjacent to a target, and
cold ablating material off the target by focusing a number of consecutive laser pulses on the target, thus producing a number of consecutive plasma fronts that move at least partly to the direction of said body, and scanning the focal spot of said laser pulses on the surface of the target;
wherein the time difference between said consecutive laser pulses is so short that on a surface of said body, constituents resulting from a number of consecutive plasma fronts form a nucleus where a mean energy of said constituents allows the spontaneous formation of a crystalline structure.

59. A method for producing particles with crystalline structure, comprising:
cold ablating material off a target by focusing a number of consecutive laser pulses on the target, thus producing a number of consecutive plasma fronts that move at least partly to a direction away from said target, and scanning the focal spot of said laser pulses on the surface of the target;
wherein the time difference between said consecutive laser pulses is so short that in a reaction space located off the target, constituents resulting from a number of consecutive plasma fronts form a nucleus where a mean energy of said constituents allows the spontaneous formation of a crystalline structure.

60. An arrangement for producing particles with crystalline structure, comprising:
a target holding unit (104) configured to hold a target (103) in place,
a laser pulse generation unit (101) configured to generate a pulsed laser beam capable of cold ablating the material of said target (103), and
laser optics (102) configured to guide the pulsed laser beam to said target (103) for producing a number of consecutive plasma fronts that move at least partly to a direction away from said target and configured to scan the focal spot of said laser pulses on the surface of the target;
characterized in that the laser pulse generation unit (101) is configured to use a time difference between consecutive laser pulses that is so short that in a reaction space located off the target, constituents (201, 202, 203) resulting from a number of consecutive plasma fronts form a nucleus where a mean energy of said constituents allows the spontaneous formation of a crystalline structure.
